(19) United States
(12) Patent Application Publication
(10) Pub. No.: US 2012/0006383 A1
(43) Pub. Date: Jan. 12, 2012

(54) HEAT EXCHANGER APPARATUS AND METHODS OF MANUFACTURING CROSS REFERENCE

(76) Inventor: Sean M. Donnelly, Portland, OR (US)

(21) Appl. No.: 13/130,370

(22) PCT Filed: Nov. 19, 2009
(86) PCT No.: PCT/US09/65221

§ 371 Date: Aug. 8, 2011

Related U.S. Application Data
(62) Division of application No. 61/116,637, filed on Nov. 20, 2008.

(51) Int. Cl. H01L 31/052; H01L 31/024; H05K 7/20; F28D 15/00

(52) U.S. Cl. 136/246; 165/104.28; 165/104.33; 136/259; 361/689

(57) ABSTRACT

The invention provides systems and methods for cooling semiconductor devices, such as those provided in concentrated photovoltaic (CPV) systems using a cold plate. The invention also provides using a material, such as a ceramic, to form that cold plate that matches or nearly matches the coefficient of thermal expansion (CTE) of a photovoltaic cell. Additionally, the cooling system may include fluidic passageways through which a fluid may flow, which may result in a transfer of heat between the fluid and the solid structure.

### CROSS REFERENCE

This application claims the benefit of priority to U.S. Provisional Patent Application No. 61/116,637 filed on Nov. 20, 2008, which is incorporated herein by reference in its entirety.

### BACKGROUND OF THE INVENTION

Solar cells have been used to convert solar energy into other forms of energy, such as electrical energy or thermal energy. Solar cells may be interconnected and may be bonded to a substrate to form a receiver. In some instances, concentrated photovoltaic (CPV) solar receivers may receive concentrated solar energy, which may be concentrated by optics and/or the reflection of solar energy from multiple reflective surfaces. In such situations, CPV receivers may generate electricity proportionally to the light flux they receive. Their efficiency is reduced as temperature increases. For example, solar cells that reach a temperature higher than 60 degrees Celsius lose between 10.5% and 17.5% of the power versus power generated at 25 degrees Celsius. A solar cell with an efficiency of 16% at 25 degrees Celsius may have an efficiency of 13.2% at 60 degrees Celsius.

Previous solutions have included mounting a natural convection aluminum heat sink on the back of a solar panel to cool the solar cells. See e.g., U.S. Pat. No. 4,118,249, which is hereby incorporated by reference in its entirety. In some instances, a fluid may pass through a heat sink to assist with cooling the solar panel or cell. See e.g., U.S. Pat. No. 4,830,678; U.S. Patent Application No. 2004/0103680; PCT Publication No. WO 2008/025004; A. Royne, C. J. Dey, and D. R. Mills, “Cooling of photovoltaic cells under concentrated illumination: a critical review,” Solar Energy Materials and Solar Cells, vol. 86, April 2005, pp. 451-483; which are hereby incorporated by reference in their entirety. Another previous solution included using a dielectric layer to insulate the back of a solar cell from a metal heat sink. See PCT Publication No. WO 2003/023869, which is hereby incorporated by reference in its entirety. However, the use of such a dielectric layer requires a large number of critical thermal interfaces and large area thermal interface materials.

Therefore, a need exists for an improved heat transfer device for transferring heat between various objects. A further need exists for a heat transfer device capable of transferring heat from a solar cell to a fluid.

### SUMMARY OF THE INVENTION

The invention provides systems and methods for thermal management of solar receivers that may enable solar receivers to operate more efficiently. The invention further provides a cold plate that may effectively transfer heat between a solid and a fluid. Various aspects of the invention described herein may be applied to any of the particular applications set forth below or for other types of energy generation or transfer systems. The invention may be applied as a standalone system or method, or as part of an application, such as a heat transfer application. It shall be understood that different aspects of the invention can be appreciated individually, collectively, or in combination with each other.

This invention describes systems and methods for thermal management of solar receivers using a coefficient of thermal expansion (CTE) matched cold plate in accordance with one aspect of the invention. The CTE of a cold plate may match or nearly match the CTE of the substrate of a solar cell. Alternatively, a CTE of a cold plate may match or nearly match the CTE of a superstrate of a solar cell. Any discussion herein of a substrate may also apply to a superstrate. The cold plate may also have high thermal conductivity. A solar cell may be directly affixed or adhered to a metallized portion of a cold plate. The cold plate may be formed of a material such as a ceramic, cermet, or a metal-matrix composite.

Another aspect of the invention provides for cold plate configurations and arrangements. Fluidic passages may be arranged through the cold plate such that heat may be effectively transferred from a solid structure to a fluid flowing within the cold plate or vice versa. A cold plate may be formed of layers that may include slots and/or holes that may form the fluidic passages. A cold plate may utilize three-dimensional fluid flow to effectively transfer heat.

One aspect of the invention provides for dense-array secondary concentration, which may result from the cold plate materials and configurations. The cold plate may enable a greater concentration and/or efficiency of solar cells, which may result in lower cost and greater power generation. The cold plate may also result in relaxed requirements for a primary concentrator or other optics.

Other goals and advantages of the invention will be further appreciated and understood when considered in conjunction with the following description and accompanying drawings. While the following description may contain specific details describing particular embodiments of the invention, this should not be construed as limitations to the scope of the invention but rather as an exemplification of preferable embodiments. For each aspect of the invention, many variations are possible as suggested herein that are known to those of ordinary skill in the art. A variety of changes and modifications can be made within the scope of the invention without departing from the spirit thereof.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings of which:

FIG. 1 shows an example of a solar module in accordance with one embodiment of the invention.

FIG. 2 shows an example of a fluid cooling system that cools solar cells.

FIG. 3 shows an example of a fluid cooling system for a device.

FIG. 4 shows an example of a concentrated photovoltaic (CPV) receiver.

FIG. 5 shows an exploded view of a module.

FIG. 6A shows an example of a heat acquisition surface in a right-handed coordinate system.

FIG. 6B shows an example of one group of fluidic passages.

FIG. 6C shows an example of a siamesed group.

FIG. 6D shows an example of an arrangement of groups on a heat transfer matrix.

FIG. 7 shows a view of a heat transfer matrix cross-section.

FIG. 8 shows an exploded view showing individual layers of a heat transfer matrix.

FIG. 9 shows a concentrating photovoltaic receiver cold plate in accordance with an embodiment of the invention.

### DETAILED DESCRIPTION OF THE INVENTION

While preferable embodiments of the invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention.

The invention provides cooling systems for a solar receiver. A solar receiver may be a photovoltaic receiver, such as a concentrated photovoltaic (CPV) receiver. A solar receiver may be mounted into a structure, such as a solar tower, a dish concentrator, or a multi-purpose structure. A CPV receiver may comprise a plurality of cells, one or more cold plate, and a cooling manifold. A receiver may comprise a plurality of modules (which may be referenced to in some instances as tiles). Modules may be arranged into an array to form a receiver. One or more modules forming a portion of a receiver may also be referred to as a subarray. In preferable embodiments, a receiver may comprise a rectangular array of modules. However, a receiver may have any shape. For example, a receiver may have a roughly circular shape, with rectangular or other shaped modules. In another example, a receiver may not have a planar shape, and may have a shape such as a bowl or trough. A cold plate shape may be adapted to accommodate a non-planar receiver.

Any number of cold plates or modules may be used to form a receiver. In some situations, one cold plate may be provided per module. In some embodiments, a receiver may be formed of an array of modules. For example, a solar receiver may comprise approximately 50 modules, 20-40 modules, 40-60 modules, 60-100 modules, 100-400 modules, or may comprise any number of modules. In some cases, a module may be approximately five inches by five inches in area, and about 2-3 inches thick. Dimensions for receivers and modules may vary.

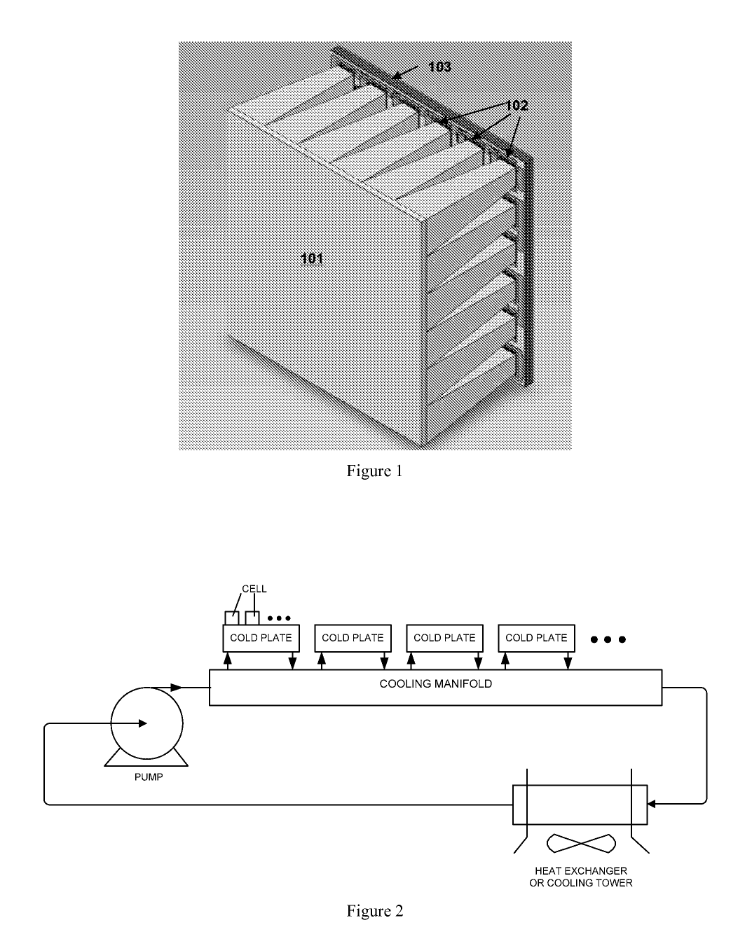

FIG. 1 shows an example of a module in accordance with one embodiment of the invention. A module may comprise optics 101, a plurality of solar cells 102, and a cold plate 103. In some embodiments, the optics 101 may be secondary optics. Secondary optics may have a configuration that may create alleys that may make cold plate design and/or electrical routing and component placement easier. A receiver may have an additional primary optic. In a preferable embodiment, each module may have its own cold plate. Multiple cold plates may be connected to a cooling manifold directly, or may be connected to one another, or a combination of both.

FIG. 2 shows one embodiment of the invention where a cooling manifold may be connected to a plurality of cold plates, each of which may be connected to a plurality of solar cells. A fluid may be driven through the cooling manifold through any driving means known in the art, such as a pump. The fluid leaving the cooling manifold may pass through a heat exchanger or a cooling tower. In preferable embodiments, the fluid entering the cooling manifold may have a lower temperature than the fluid leaving the cooling manifold. Fluid from a fluid source of the cooling manifold may flow to one or more inlets of a cold plate. The fluid may flow through the cold plate and may leave the cold plate through one or more outlets of the cold plate. The outlets may connect to a fluid sink portion of the cooling manifold. In some embodiments, the fluid source and fluid sink portions of the cooling manifold may be kept separate, while in other embodiments, they may be the same, share components, or interact with one another.

In alternate embodiments, modules may comprise a portion of a cooling plate; for example, a receiver may have one cold plate, and all of the modules may include optics, solar cells, and the portion of the cold plate that the solar cells of the tile are contacting. In such a situation, one cold plate may cool the entire receiver, including all of the solar cells of the various modules and groups of modules. In such a situation, the one cold plate may be connected to a cooling manifold, or may function as the cooling manifold. In some other embodiments, a receiver may have a plurality of cold plates, but modules may share cold plates.

Any fluid may flow through the cooling manifold and/or cold plate. For example, a fluid may be a liquid, such as water, or a gas, such as air. The fluid may be a coolant. In a preferable embodiment of the invention, the same fluid may circulate throughout the cooling system. In other embodiments, different fluids, which may have different fluid properties may flow through different regions of the cooling system. This may be desirable in situations where the amount of desired heat transfer may vary in different regions.

In some embodiments, the rate of fluid flow may remain substantially constant. In other embodiments, the rate of fluid flow may be varied. For example, a variable speed pump may be used to change the rate of forced fluid flow, which may result in a change of exit temperature of the fluid, which may affect the temperature of the solar cells. Depending on the amount of solar concentration that a solar cell is receiving, a desired fluid flow rate may exist in order to achieve a desired temperature.

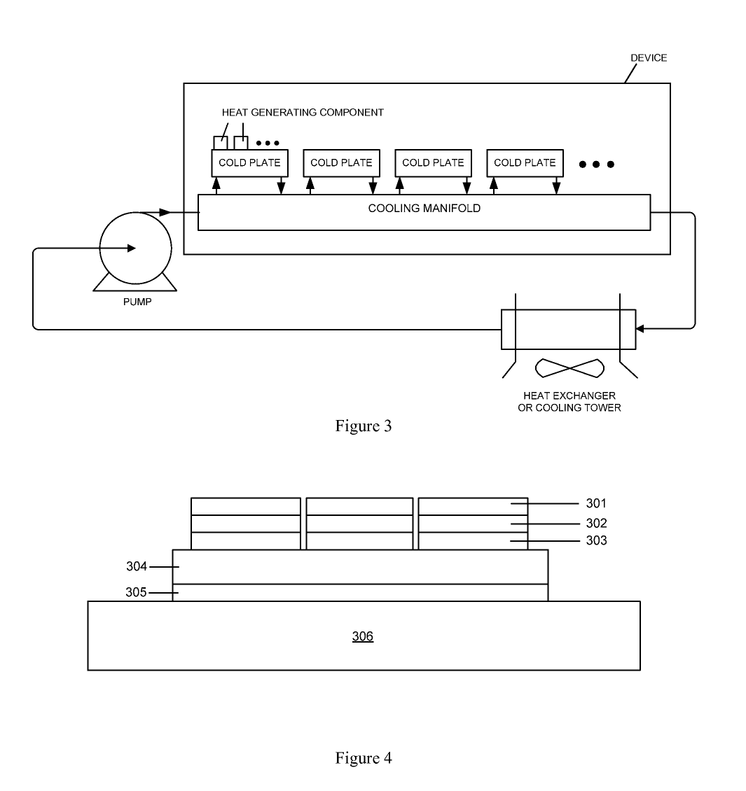

FIG. 3 provides another embodiment of the invention where a cooling manifold may be connected to a plurality of cold plates. The cold plates may each be connected to a plurality of heat-generating components. As previously described, heat-generating components may include solar cells, such as photovoltaic cells. In other examples, heat-generating components may include semiconductor devices, chips, microprocessors, integrated circuits, diodes (e.g., LEDs), and/or transistors (e.g., IGBTs). Any other heat source or object to be cooled may be directly or indirectly contacting the cold plate or in thermal communication with the cold plate.

In some embodiments, a device may comprise a cooling manifold, one or more cold plate, and one or more heat sources thermally connected to the one or more cold plate. In some embodiments, the device may be a solar receiver or a solar module. In other embodiments, the device may be a computer, any other electronics or semiconductor device, or any other apparatus that may be cooled. In some embodiments, the device may or may not include the cooling manifold and/or the cold plate. The device may include the heat sources.

I. CTE Matching

One aspect of the invention provides a coefficient of thermal expansion (CTE) matched cold plate. A cold plate may be CTE matched with one or more solar cells or solar cell components. For instance, the cold plate CTE may substantially match the CTE of a solar cell substrate. Thus, as the temperature of a solar cell and/or cold plate may change, by having the same or substantially similar CTE's, the solar cells and cold plates may expand or contract the same or a similar amount, and thereby have less stress at their interfaces.

In some embodiments of the invention, the cold plate may be used to cool any object that may be connected to it. In some embodiments, the object to be cooled may be a solar cell. In other embodiments, the object to be cooled may be another semiconductor device, such as a transistor (including IGBTs), diodes (including LEDs), microprocessors, and so forth. In such situations, the cold plate may have a CTE that matches or nearly matches the CTE of the object to be cooled. Any discussion herein of solar cells, modules or receivers may apply to other heat-generating components and devices.

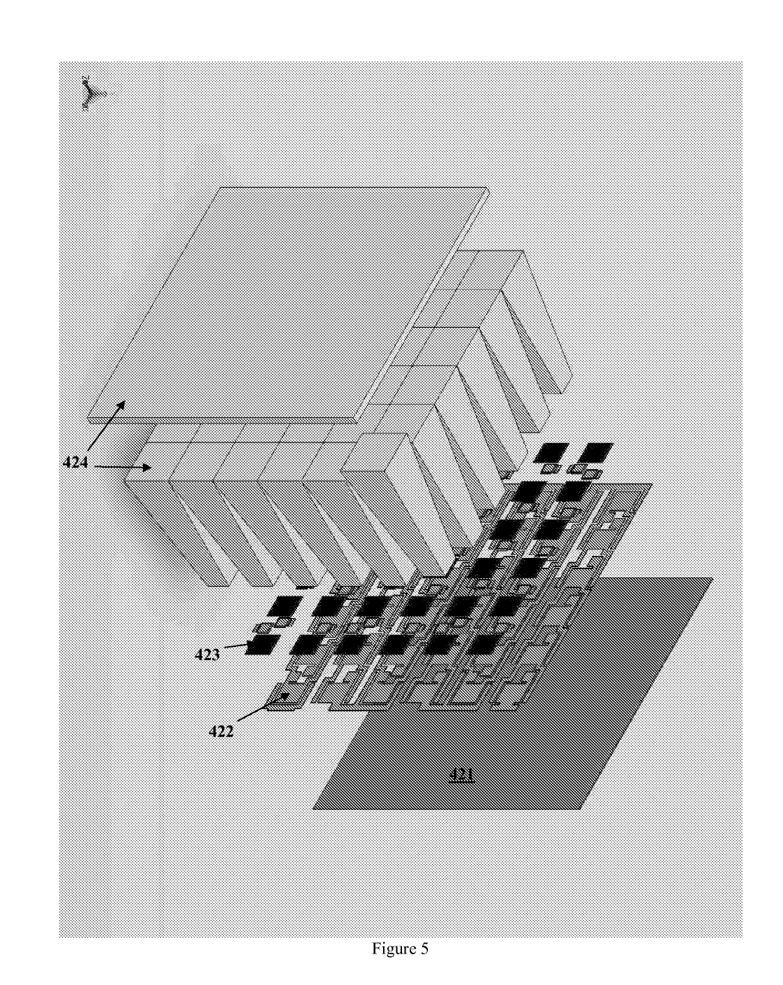

FIG. 4 shows a side view of a module of a solar receiver in accordance with one embodiment of the invention. In some embodiments, the solar receiver may be a photovoltaic receiver, such as a CPV receiver. A CPV receiver module may include one or more solar cells 301, along with any interfacing or interconnecting components 302, 303, a cold plate 304, a fluid seal 305, and a receiver backplane and coolant manifold 306. In some embodiments, a solar cell 301 may be a multi junction cell. The solar cell may be connected to the cold plate 304 through a thermal interface material (TIM) 302, and on circuit traces 303, which may be imprinted on the cold plate 304.

The solar cell may be any cell known in the art, including, but not limited to cells with a germanium substrate. Cells may comprise indium gallium phosphide, gallium arsenide, indium gallium arsenide, and/or germanium, and may be fabricated on a germanium base. Alternatively, cells may have a gallium arsenide substrate or an indium phosphide substrate. Solar cells may also be silicon solar cells, cadmium telluride solar cells, copper-indium selenide solar cells, copper indium gallium selenide solar cells, dye-sensitized solar cells, or organic or polymer solar cells.

The solar cell may be connected to the cold plate through a TIM. The TIM may be an adhesive that allows a solar cell to be affixed to the cold plate. The TIM may be any material known in the art, such as soft solder. A TIM may include metal, namely a solder, preferable solders which may include Sn—Ag—Cu soft solders, Sn—Pb soft solders, or Au—Sn hard solders. The TIM may also be a grease or gel, which may or may not include particles, such as ceramic or metallic particles. A solder paste, such as Sn62, may also be used for the TIM. The TIM could also be any conductive adhesive known in the art, such as a metal or ceramic loaded epoxy (e.g., Diemat DM6030Hk). Various silicone or acrylic adhesives may be used as well.

A solar cell may be connected to a metallized portion of the cold plate. The metallized portion may form circuit traces. The circuit traces may be formed of any metal known in the art. For example, circuit traces may comprise copper, aluminum, silver, platinum, and/or tungsten. The cold plate may be metallized using any method known in the art. For example, a metal may be deposited on the cold plate material using a screen print and/or sinter process or chemical vapor deposition and plating process. Patterns may be etched into the metal face. An etching process can utilize a strong chemical etch, such as an acid bath, or a mechanical etc, such as microblasting small abrasive particles through a mask. A circuit pattern, which may interconnect solar cells into a series or parallel circuit (or some combination thereof) may be etched into the metal, which may be direct bonded to the cold plate. Possible fabrication methods are discussed in greater detail below.

In some embodiments, due to the relatively small amount of adhesive/solder and circuit traces, the effects of the CTE of these materials are relatively small or negligible compared to the effects of the CTE of the solar cells and cold plate. Thus, CTE-matching the solar cells and cold plate may sufficiently reduce stress at their interface.

The fluid seal may be formed of any material known in the art that may effectively function as a fluid seal. For example, the fluid seal may be formed of an elastomer, such as ethylene propylene diene M-class (EPDM) rubber. In other embodiments, the fluid seal may include synthetic rubbers, such as butadiene rubber (BR), butyl rubber (IIR), chlorosulfonated polyethylene (CSM), epichiorohydrin rubber (ECH, ECO), ethylene propylene rubber (EPR), fluoroelastomers (FKM), nitrile rubber (NBR), perfluoroelastomer (FFKM), polyacrylate rubber(ACM), polychloroprene (CR), polyisoprene (IR), polysulfide rubber (PSR), silicone rubber (SiR), or styrene butadiene rubber (SBR). The fluid seal may also include thermoplastics, such as thermoplastic elastomer (TPE) styrenics; thermoplastic polyolefin (TPO) LDPE, HDPE, LLDPE, ULDPE; thermoplastic polyurethane (TPU) polyether, polyester; thermoplastic etheresterelastomers (TEEEs) copolyesters; thermoplastic polyamide (PEBA) polyamides; melt processible rubber (MPR); or thermoplastic vulcanizate (TPV).

In some embodiments, solar cells may directly contact the cold plate, and may not require any intermediate dielectric layers. A solar cell may be in contact with a TIM, which may be in contact with circuit traces of a cold plate. Alternatively, a solar cell may directly be in contact with the circuit traces of the cold plate, and may be connected by some means other than a TIM. The solar cell may be in thermal contact with the cold plate as well. Many configurations may be provided where a solar cell may have a proximate relationship with a cold plate. The solar cell and the cold plate may have a CTE-matched or substantially CTE-matched interface.

The cold plate may be formed of any material that may be CTE-matched or substantially CTE matched with a component that is connected to it. In some embodiments, the CTE of the cold plate may fall within a predetermined range relative to the CTE of the component connected to it. For example, the CTE's of a cold plate and a solar cell or other semiconductor device may be within 1 ppm/K, may be within 0.5 ppm/K, may be within 0.2 ppm/K, or may be within 0.1 ppm/K. Or a predetermined range may be defined as a multiplier. For example, the CTE of a cold plate may be greater than 0.50 times the CTE of the component connected to it (such as a semiconductor device), and less than 2.0 times the CTE of the component connected to it. Alternatively, the CTE of the cold plate may be greater than 0.5 times, 0.7 times, 0.75 times, 0.9 times, 1.0 times, 1.2 times, 1.3 times, 1.5 times, or 1.7 times, and/or less than 0.7 times, 0.9 times, 1.0 times, 1.2 times, 1.3 times, 1.5 times, 1.7 times, 1.9 times, or 2.0 times the CTE of the component connected to it. For example, the cold plate may be formed of a material that may be substantially CTE-matched to a solar cell or substrate of a solar cell, such as germanium. The two materials (e.g., the cold plate material and the solar cell material) may have relatively compatible CTE's.

In some embodiments, it may be preferable for a cold plate to be formed of a low-CTE and/or high k material (where k refers to a measure of thermal conductivity). Some examples of materials that may be used to form the cold plate are ceramics, cermet, or a metal-matrix composite with a thin film insulator. Preferably, materials used to form the cold plate may include oxide ceramics, nitride ceramics, silicon-aluminum alloys or composites, tungsten-copper composites, and/or mixtures or combinations thereof.

A preferable embodiment of the invention may provide a material with an increased thermal conductivity (k), a CTE of about 6.5 ppm/K, and the ability to accept patterned metallization. Some examples of materials that may be included in the formation of the cold plate are alumina, beryllium oxide, aluminum nitride plus approximately 5% yttria, or a composite containing alternating alumina and aluminum nitride layers. A cold plate material may include any material with a k>20 W/mK, and whose CTE falls between 0.50 to 2.0 times the CTE of an object to be cooled. In some embodiments, the cold plate material may include any material with k>1 W/mK, 3 W/mK, 5 W/mK, 7 W/mK, 10 W/mK, 15 W/mK, 18 W/mK, 22 W/mK, 25 W/mK, 30 W/mK, or 40 W/mK. In other embodiments, the cold material CTE may fall between 0.5 to 2.0 times, 0.6 to 1.9 times, 0.7 to 1.7 times, 0.75 to 1.5 times, 0.8 to 1.4 times, 0.9 to 1.3 times, or 1.0 to 1.2 times the CTE of the object to be cooled. In some instances, the cold plate material CTE may be approximately 0.5 times, 0.6 times, 0.65 times, 0.7 times, 0.75 times, 0.8 times, 0.85 times, 0.9 times, 1.0 times, 1.1 times, 1.2 times, 1.3 times, 1.4 times, 1.45 times, 1.5 times, 1.55 times, 1.6 times, 1.7 times, 1.8 times, 1.9 times, or about 2.0 times the CTE of the object to be cooled.

In some embodiments, a cold plate may be formed of a material, and may include holes that could be filled with a second material. The second material may be a metal, such as tungsten, aluminum, copper, platinum, or silver. These may be referred to as thermal vias. Thermal vias may be oriented perpendicular to the surface of a cold plate that may contact an object to be cooled; alternatively, the thermal vias may have any orientation. The thermal vias may provide a way of affecting thermal conductivity of the cold plate with relation to a CTE. For example, using metallic thermal vias may result in an increased thermal conductivity, while not affecting the CTE a large amount.

Additional views of a solar module with accompanying components may be provided. FIG. 5 shows an exploded view of a module. FIG. 5 shows a cold plate 421 along with metallization 422. The metallization may have any pattern. The metallization pattern may connect solar cells in a desired manner. For instance, the metallization may form circuit traces that may electrically interconnect solar cells in series, in parallel, or some combination thereof. The cold plate 421 with metallization 422 may also have solar cells 423 that are positioned over the metallization. In one example, there may be an arrangement of six by six solar cells on a cold plate. In various embodiments of the invention, any number of solar cells may be placed onto a cold plate. For example, there may be 4-9, 10-20, 21-50, or 51-100 solar cells placed on a cold plate. Solar cells may have any dimensions or spaces provided between. Using more closely-matched CTE materials for cold plates may enable larger solar cells.

FIG. 5 shows an exploded view of a cold plate 421, along with metallization 422, solar cells 423, and optical elements 424. These elements may combine to form a module. The optics 424 may be transparent, so that when looking from a top view of the module, one may see the underlying solar cells 423, circuit traces 422, and cold plate 421.

One advantage of using such a cold plate may include having a high cycle lifetime. A more durable material may be used to form the cold plate. Also, reduced stresses from having a CTE matched interface may result in a greater lifetime for the cold plate and/or solar cells. This may enable the module to maintain integrity of the solder/adhesive joint over many thermal cycles. An increased lifetime of materials may result in lowered operation and maintenance costs.

The use of CTE-matched materials to form a cold plate may also result in fewer thermal interfaces for a solar receiver. This may result in lower manufacturing costs, higher production yields, lower inspection costs, higher reliability, and lower thermal resistance.

Another advantage of using a CTE-matched cold plate may be that a larger module size may be used, since module size may not be as limited by thermomechanical effects, such as thermal expansion. Having a larger module may result in higher output voltage. Furthermore, fewer interconnections may be required, which may reduce assembly costs and provide fewer possibilities for failure.

CTE-matched cold plates may also advantageously allow the use of larger cells. Since the CTE of the solar cells and an adjacent cold plate may be closer matched, this may enable the use of larger solar cells since thermal expansion may not cause stresses along the interface, or may provide only minimal stresses along the interface. The use of larger cells may result in higher production yields. The use of larger cells may also reduce the number of parts or complexity of a receiver. Similarly, solar cells may be spaced more closely into a denser array or configuration.

Cell temperature may no longer be limited by thermomechanical effects. This may enable a higher solar concentration to be provided to the solar cells per area. In some embodiments, four times higher concentration may be provided, as compared to traditional solar CPV receivers. Furthermore, a greater density of solar cells may be provided. For instance, more solar cells may be fit within a given area as compared to traditional solar receiver sections. For instance, solar cells (which may have any dimension, which may be on the order of 0.25 square cm, 0.5 square cm, 1 square cm, 2 square cm, 5 square cm, or 10 square cm) may be in contact with a cold plate. Any amount of space between solar cells may be provided. For example, the distance between cells, edge to edge, may fall within approximately 0.1 to 5 cm. Furthermore, costs of the cold plate may be reduced (such as by four times) and pumping parasitics may be reduced.

Additionally, using a CTE matched cold plate may enable solar cells to operate at higher temperatures. Although this may still result in decreased efficiency of solar cells, the stresses that would have resulted from different CTE's are reduced, and may enable a greater amount of thermal expansion before any stresses occur. Thus, the flow rate of a fluid to a solar receiver may be adjusted to generate a higher exit temperature of the fluid. In some embodiments, the flow rate may be adjusted by a program or control. For example, a program or control may be provided that may determine a desired flow rate for given conditions. Such controls may be provided automatically, or may be applied by user interaction. Thus, thermal output may have an increased economic value. The solar cells may not be damaged due to the CTE matching, and may operate at temperatures greater than 150 degrees Celsius. The “hot” fluid may be used in other applications, such as absorption or adsorption cooling, water purification, process steam, waste heat recovery electric power generation, or thermal energy storage. In some embodiments, solar receivers may be combined with multi-purpose towers that may utilize the “hot” fluid for various purposes.

II. Fluidic Passage Configurations

The invention provides cooling plate configurations and formats in accordance with another aspect of the invention. The cooling plate may comprise microchannels that may enable the flow of a fluid within the cooling plate. The cooling plate may be a microfluidic heat exchanger. Fluid flow may be used to transfer heat from a solid object to the fluid, or from the fluid to a solid object. See e.g., U.S. Pat. No. 6,935,411 and U.S. Pat. No. 7,302,998, which are herein incorporated by reference in their entirety. Any discussion of microchannels or microfluidic channels herein may refer to any fluid passage which may have any arrangement or configuration, to be discussed in greater detail below.

The cooling plate may have various characteristics, such as low thermal resistance, high uniformity, high immunity to plugging, and/or high effectiveness. For example, a thermal resistance R″ may be less than 0.4° C. cm² W⁻¹. An inlet-to-outlet pressure drop Δp may be less than 20 kPa, or alternatively may be less than 15 kPa, 10 kPa, or 5 kPa. An effectiveness s may be greater than 0.7, or alternatively may be greater than 0.8, 0.9, 0.95, 0.97, or 0.99.

The cooling plate may comprise passages for fluid to flow in directions parallel to the heat acquisition surface, normal to the heat acquisition surface, and/or may create a three-dimensional flow pattern. As a fluid may flow in a direction parallel to the heat acquisition surface, the temperature of the fluid may increase, and the temperature of various components of a heat acquisition interface may also increase correspondingly. For a parallel-flow microchannel, at a high flow rate, there may be a low R″, high Δp, low ε, and good uniformity. At a low flow rate, there may be a high R″, low Δp, a high ε, and poor uniformity.

As a fluid may flow in a direction normal to the heat acquisition surface, the temperature of the fluid may increase as it flows along a fin and approaches the heat acquisition interface. For a normal-flow microchannel, in a high-k material, there may be a large amount of parasitic heat transfer, resulting in a low R″, low Δp, and low ε. In a low-k material, parasitic heat transfer may be reduced, but R″ may be high.

In a preferable embodiment of the invention, the cooling plate may comprise microchannels that can combine parallel and normal-flow characteristics, which may include a low R″, low Δp, high ε, and good uniformity. Characteristics such as uniformity and c may not be sensitive to flow rate.

A cooling plate may include any number or configuration of microchannels. The microchannels may be curved, straight, or may have sharp corners. The microchannels may have any relative orientation to one another and the cooling plate. Any further discussion of microchannels or fluid passages are provided by way of example only.

In describing the invention, a right-handed coordinate system xyz having orthogonal axes x, y, and z may be used as a reference. For clarity, features of the invention may be described as being oriented in specific directions (e.g. +x or −z) or lying in specific planes (e.g. a plane parallel to y and z). These descriptions are for illustration only and do not exclude the use of features that are not orthogonal to x, y, or z or are not rectilinear.

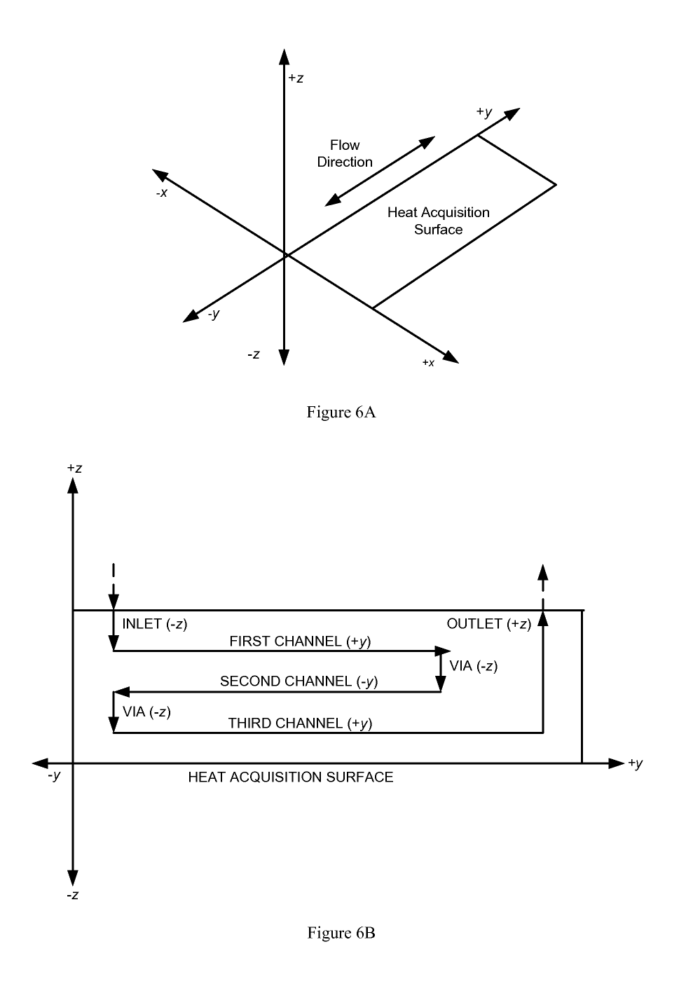

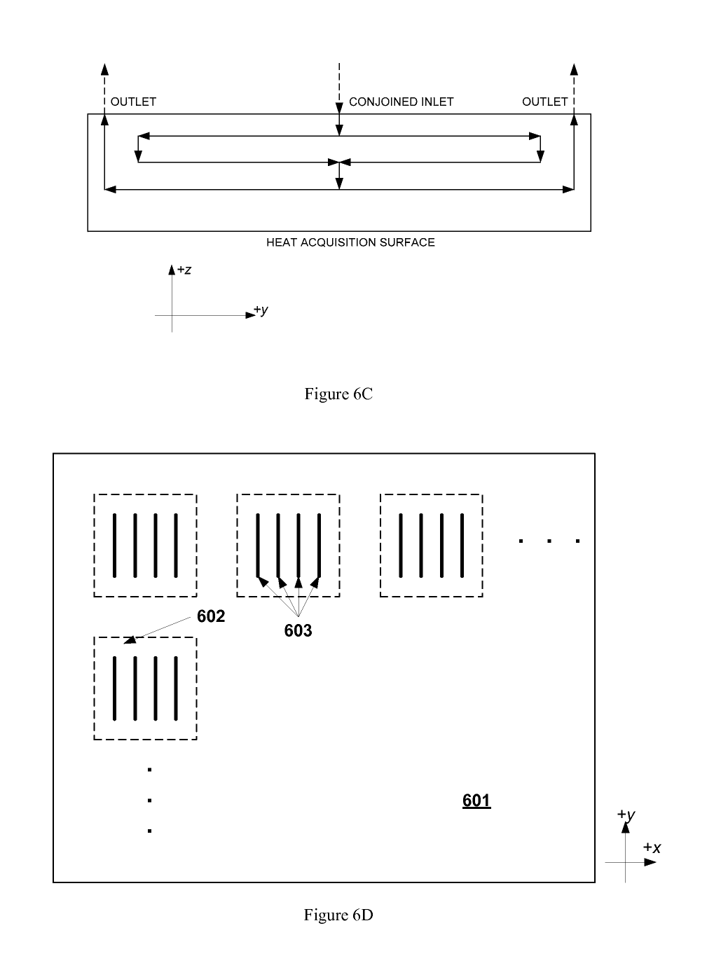

The invention provides a cooling plate that may directly or indirectly contact an object to be cooled. FIG. 6A shows an example of a heat acquisition surface in a right-handed coordinate system. The object to be cooled may typically be attached to a planar surface (the heat acquisition surface) parallel to x and y. In some embodiments, the object to be cooled may be a solar cell. The cooling plate may comprise a thermally conductive solid material, or composite of materials, containing a plurality of fluid passages. Such fluid passages may be described as channels, vias, inlets, and/or outlets.

A channel may have a relatively small extent in the x and z directions (the cross section) and a much larger extent in they direction (the flow direction). Thus in one embodiment of the invention, a channel may refer to a fluid passage that is oriented along they direction. A length of a channel may describe an extent of the channel in they direction.

A channel may have any configuration that may enable fluidic flow. For example, the cross section may have any shape, including but not limited to squares, circles, ellipses, rectangles, triangles, pentagons, any other polygon, or any other regular or irregular shape. The shape of a channel cross-section may or may not vary along the length of the channel.

The dimensions of a channel cross-section in x and z directions may be similar. For example, the dimensions of a channel-cross section may be within a factor of two. In other embodiments, the dimensions of the channel cross-section may vary and may or may not be similar. The dimensions of a channel cross-section may or may not vary along the length of the channel, and proportion of the dimensions may or may not vary along the length of the channel.

In a typical implementation of the invention, channels may be arranged in a three-dimensional array in the x, y, and z directions. In some embodiments the channels may all be oriented along they direction or in any other direction, including but not limited to the x and z direction. In other embodiments, some of the channels may be oriented along one direction while other channels are oriented along a second, non-parallel direction.

One function of a channel may be to transfer heat from a solid structure to a fluid, or vice versa. For instance, an object to be cooled may be in contact with the cooling plate surface. A fluid may flow through the fluid passages, such as the channels. Heat may be transferred from the object to be cooled to the cooling plate surface to the fluid. In another embodiment, heat may be transferred from a fluid to a cooling plate surface to an object in contact with the cooling plate surface. In some examples, the cooling plate may be a microfluidic heat exchanger with two substantially planar opposing surfaces. A first surface may be in thermal contact with a heat acquisition surface (e.g., an object to be cooled, or a surface contacting the object to be cooled). A second surface may be opposing and/or substantially parallel to the first surface. The second surface may be formed with an inlet and outlet. A plurality of fluid passages may be in fluid communication with the inlet and outlet. The plurality of fluid passages may be formed between the two substantially planar opposing surfaces.

A via may be a fluid passage that can interconnect adjacent channels along the z direction. Thus, in one embodiment of the invention, a via may refer to a fluid passage that is oriented in the z direction. A via may have a relatively small extent in the x and y directions (the cross section). The length of the via and the flow along a via may be in the z direction. In some embodiments, a via may be short relative to the length of a channel in they direction. Like a channel, a via may have any cross-sectional shape, dimensions, and proportion, which may or may not change along the length of the via. One function of a via may be fluidic interconnection. A via may connect channels at the end of the channels or anywhere along the length of the channels. An additional function of the via may be that it can provide additional heat transfer between the solid structure and the fluid.

An inlet may connect a channel or via to an inlet port on an exterior surface of the device, which may be connected to a fluid source. An outlet may connect a channel or via to an outlet port on an exterior surface of the device, which may be connected to a fluid sink. In some embodiments, the fluid source and/or fluid sink may be part of a receiver backplane and/or cooling manifold. In one implementation of the invention, the inlet ports and outlet ports may be located on a planar surface parallel to and opposite from the heat acquisition surface. Flow through the inlets and outlets may be predominantly in the −z and +z directions, respectively.

However, alternate implementations may extend the inlets and outlets in additional directions, and/or connect them together via manifolds or plena, as needed to provide a desired arrangement of fluid interfaces. For instance, an inlet and outlet may be on any surface of the cooling plate. In some embodiments, the inlet and outlet may be on the same surface, while in other embodiments, they may be on different surfaces. In one example, the inlet and outlet may be on a surface that is opposing a surface in thermal communication with a heat acquisition surface. The inlet and outlet may also have any orientation. The inlet and outlet may or may not be parallel to one another. In some embodiments, there may be a plurality of inlets and/or a plurality of outlets. The plurality of inlets and/or outlets may be located anywhere on the cold plate surface and may have any orientation.

The fluid passages, which may include channels, vias, inlet, and outlet, may be arranged to provide a series/parallel network of flow paths. For example, a set of n channels, where n may be an odd integer greater than or equal to three, may be interconnected by (n−1) vias and connected to an inlet and an outlet to form a group. Each channel in a group may lie at a different distance (z coordinate) from the heat acquisition surface.

FIG. 6B shows an example of one group in accordance with one embodiment of the invention. In a basic implementation of the invention, a group may consist of one inlet, three channels, two vias, and one outlet. Fluid may flow in the −z direction through the inlet to a first channel (the one furthest from the heat acquisition surface), then through the first channel in the +y direction, then through a via in the −z direction to a second channel, then through the second channel in the −y direction, then through a via in the −z direction to a third channel (the one closest to the heat acquisition surface), then through the third channel in the +y direction to the outlet, then in the +z direction though the outlet. The third channel may be longer (in they direction) than the first and second channels to provide separation between the outlet and the other fluid passages.

The device may contain one or more groups like the one described above, arrayed along the x and y directions, through which fluid may flow in parallel. For example, the device may contain groups aligned in parallel to the first group, which may also be oriented along they direction. The groups may be arranged such that they are adjacent to one another and that inlets and outlets for the groups are aligned along the x direction. The device may include groups that are arranged in parallel, but that are staggered such that the inlets and outlets are not aligned, or such that the placement of the inlets and outlets are reversed. The device may also contain some groups that may be aligned in different directions, such as the x direction, or at any angle.

In other implementations of the invention, the group may contain five, seven, nine, or more odd number of channels through which fluid flows alternately in the +y and −y directions in the same manner as described in for FIG. 6B.

In alternate implementations of the invention, the group may contain an even number of channels, such as two, four, six, eight, or more even number of channels. The inlet and outlet may be arranged such that they are not in close proximity to one another, for example, the lengths of the channels may be adjusted such that there may be an even number of channels and the inlet and outlet may be spaced apart from one another in they direction.

In some embodiments, the channels may be arranged such that they do not need to go back and forth along opposite directions (e.g., +y, then −y, then +y, and so forth). The channels may continue in the same direction (e.g., +y, then +y) or may go off in a completely different direction (e.g., +y, then +x, then −y, and so forth) or any combination of directions.

An odd number of channels in each group may provide spatial separation of the inlet and outlet, which may be desirable to minimize parasitic heat transfer and to facilitate sealing. Or an even number of channels may be arranged such that spatial separation exists between the inlet and outlet. This spatial separation may be enhanced by arranging groups that are adjacent along they direction in mirror-symmetric pairs, resulting in paired inlets and paired outlets. For example, going along they direction, there may be a first inlet, a first outlet corresponding to the first inlet, a second outlet, a second inlet corresponding to the second outlet, a third inlet, and a third outlet corresponding to the third inlet.

In accordance with an implementation of the invention, a heat exchanger may have one or more internal fluid passages, such as those described. The fluid may flow in a first direction substantially normal to and toward a heat transfer surface; then in a second direction substantially parallel to the said heat transfer surface; then in a third direction substantially normal to and toward the said heat transfer surface; then in a fourth direction substantially parallel to the said heat transfer surface, and substantially opposite to the second direction; then in a fifth direction substantially normal to and toward the said heat transfer surface; then in a sixth direction substantially parallel to the said heat transfer surface, and substantially opposite the fourth direction; and then in a seventh direction substantially normal to the said heat transfer surface. In any of the fluid flow directions described, the fluid may flow in the same or opposite direction to that described herein. Fewer or additional fluid flow directions may be provided.

If desired, a mirror-symmetric pair of groups can be conjoined at their inlets to form a siamesed group consisting of one inlet, n double-length channels, 3(n−1)/2 vias, and two outlets. In some embodiments, the siamesed groups may be arranged that the channels branching from the inlet may flow in opposite directions.

FIG. 6C shows a siamesed group in accordance with one embodiment of the invention. For example, a fluid may flow in the −z direction through an inlet, and then branch off into two channels, such that some of the fluid flows along the −y direction and some of the fluid flows along the +y direction. In other embodiments, the channels may be oriented such that fluid may flow in any direction. For example, the channels may be oriented such that the fluid may flow substantially in parallel, or at angles to one another, or channels may be curved or bent so that fluid may flow in any orientation with respect to fluid within another channel for a given length of channel.

After the fluid may flow along the split channels, they may continue flowing down a via, which may be oriented in the −z direction. Then the fluid may flow along second channels. These second channels may or may not meet. If they do meet, the fluid may flow down a common via in the −z direction. Then the channels may branch off again such that a third channel may allow fluid to flow in the +y direction while another third channel may allow fluid to flow in the −y direction. The fluid may then flow out of the cooling plate in the +z direction through the respective outlets. In a similar fashion, two siamesed groups can conjoined at their outlets; this process can be repeated as desired indefinitely.

Groups, which may or may not be siamesed groups, may be located in close proximity to an object to be cooled. For example, FIG. 6D shows an example of a cooling plate 601, along with a plurality of objects to be cooled 602, and a top view of one possible configuration of groups 603 in the cooling plate. The plurality of objects to be cooled may contact the cooling plate along a heat acquisition surface. The groups may be disposed within the cooling plate.

In some embodiments, there may be one outlet per inlet. In some embodiments, one inlet may correspond to any number of outlets. Similarly, one outlet may correspond to any number of inlets. For example, one inlet may branch off into any number of channels, which may have a corresponding number of outlets. In another embodiment, one inlet may branch off into a plurality of channels, which may recombine into one outlet. In some embodiments, a plurality of inlets and/or outlets may connect to channels that may intersect one another or join one another. For example, two inlets may merge into one channel which may branch off into a plurality of outlets. Or in another example, two inlets may connect to two channels, that may intersect one another, but then continue onto their respective outlets.

In some embodiments, parasitic heat transfer can be further reduced by providing a thermal break between each outlet and the adjacent channels and vias. The thermal break may consist of one or more cavities containing a material of relatively low thermal conductivity, such as air. The thermal break may also consist of any material of low thermal conductivity that may come between the outlet and adjacent fluid passages.

In some embodiments of the invention, a heat transfer matrix (which may also be referenced to as a cold plate or cooling plate) may be formed of a plurality of layers. Any number of layers may be used. The layers may contain arrays of slots and/or holes that may provide the fluidic functions. Alternatively, the layers may be formed of cermet or a metal-matrix composite. In some embodiments of the invention, the layers may be formed of a ceramic material. The layers may have any thickness. In some embodiments, all layers may have the same thickness, while in other embodiments, layer thickness may vary. In preferable embodiments, layer thickness may be uniform throughout the layer, while in other embodiments, layer thickness may vary.

In one example, the heat transfer matrix may be built up from seven H mil and two 2H mil ceramic layers, where H is any positive number, which may include a number falling within the range of 1-40 mils, such as 1, 2, 3, 4, 5, 6, 7, 8, 9, 10, 12, 15, 20, 25, 30, 35, or 40, 1-20 mils, or 8-16 mils. In some instances, the two 2H mil layers can be subdivided into pairs of identical H mil layers (e.g., to yield nine H mil layers).

In one implementation, the layers of the heat transfer matrix may each be a 100 mm, 120 mm, 140 mm, 150 mm, 160 mm, 180 mm, or 200 mm square. In preferable embodiments of the invention, each layer may have the same dimension and/or shape. In alternate embodiments, the dimensions and/or shape of each layer may vary. A layer of a heat transfer matrix may preferably have a square or rectangular shape. However, any other shape may be used for a heat transfer layer including, but not limited to circles, ellipses, hexagons, pentagons, or any other shape. In some embodiments a dimension for width or length of a layer may fall within 20 mm to 1 meter, or may fall within 120 to 200 mm, 100 to 300 mm, or 50 to 500 mm.

A heat transfer matrix may also include a layer with metal circuit traces on top. The metal circuit trace may comprise any conductive metallic material including, but not limited to, copper, aluminum, silver, platinum, or tungsten. For example a metal circuit trace may be formed of copper plated onto a thin-film or thick-film metallization of a ceramic surface.

As discussed previously, a layer of a heat transfer matrix may include slots and/or holes. In one example, a typical slot width (or hole diameter) may be 0.1 mm (about 4 mil), 0.15 mm (about 6 mil), 0.2 mm (about 8 mil), 0.25 mm (about 10 mil), 0.3 mm (about 12 mil), 0.4 mm (about 16 mil), or 0.5 mm (about 20 mil). A slot width may fall within 0.05 mm to 1.5 mm, 0.1 to 1.0 mm, or 0.15 to 0.5 mm. A typical slot spacing may be 0.2 mm (about 8 mil), 0.3 mm (about 12 mil), 0.4 mm (about 16 mil), 0.5 mm (about 20 mil), 0.6 mm (about 24 mil), 0.8 mm (about 32 mil), or 1.0 mm (about 40 mil) from center to center. A slot spacing may fall within the range of 0.1 mm to 2.0 mm, 0.2 to 1.2 mm, or 0.3 to 0.7 mm. However, dimensions, shapes, and/or placement of slots and/or holes may vary.

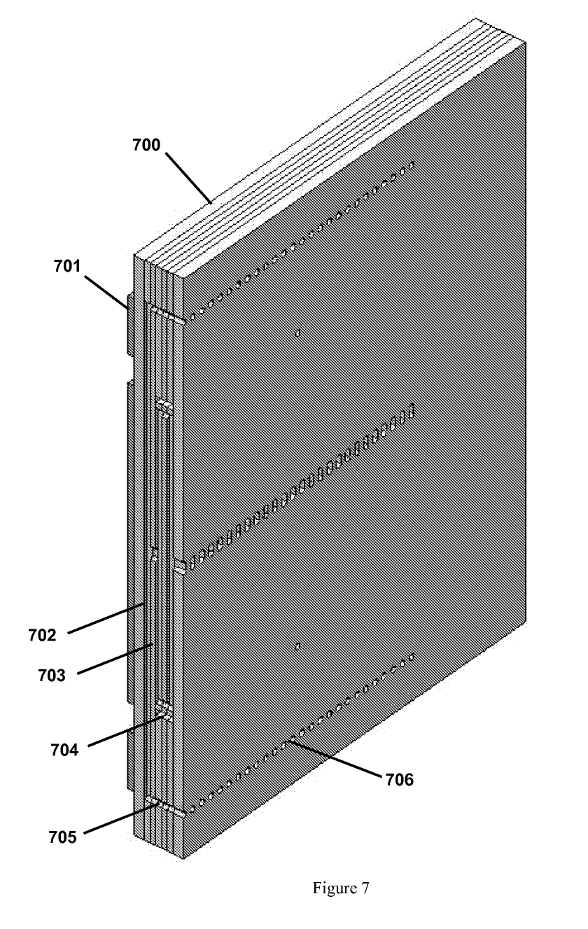

The microfluidic features may be arranged in groups. A plurality of groups may be combined to form a cluster. For example, a cluster may comprise a plurality of parallel adjacent groups. In other embodiments, the groups in the clusters may have any orientation or configuration. An array of clusters may be provided. For example, a 7×7 array of clusters may be arranged on 20 mm [0.787 inch] centers. FIG. 7 shows a view of a heat transfer matrix. The heat transfer matrix may include metallization features 701. This may be one such cluster of features. The heat transfer matrix may also include one, two, or more ceramic layers 700.

A unit may be formed of a component of a heat transfer matrix, metallization features, and one cluster of microfluidic features. Preferably, a unit may correspond to one object to be cooled, such as a solar cell. Alternatively, a unit may correspond to a plurality of objects to be cooled, or an object to be cooled may correspond to a plurality of units. In some embodiments, the metallization pattern may differ from unit to unit. A heat transfer matrix may be in contact with one or more objects to be cooled. For example, the heat transfer matrix may be connected to a 7×7 array of solar cells, and may be made up of a corresponding 7×7 array of units.

FIG. 7 shows a view of a unit cross-section. The cross section shows how there may be various microfluidic features 702, 703, 704, 705. Some microfluidic features may be formed of a slot 702, 703, and may appear to run along a layer, while other microfluidic features may be formed of holes 704, 705 that may appear to run through a layer. In some embodiments, the microfluidic features shown by the cross section may be comparable to any of the channel and via structures described in any other embodiments. In some instances, a slot in a layer may form a channel or part of a channel, and a hole in a layer may form a via or part of a via. A slot 702, 703 may run parallel to a heat acquisition surface. A via 704, 705 may run normal to a heat acquisition surface. In some embodiments, a ceramic layer may have an exposed hole 706 that may form an end of a via.

The channels and vias may have any configuration. For example, the channels and vias shown in the cross-sectional view of FIG. 7 may have a similar arrangement to the fluid flow paths shown in FIG. 6C. Alternatively, other cross-sections or other heat-transfer matrices may have channels and vias forming fluid flow paths similar to those shown in FIG. 6B or having any other fluid flow arrangement.

Along various cross-sections of a heat transfer matrix unit, there may be different microfluidic features that may be exposed. For example, in some cross-sections, a couple of microfluidic features spanning a couple of layers are revealed. Such microfluidic features may be referred to as vias.

A cutaway of a heat transfer matrix may reveal the cross-section of several microfluidic features. Such microfluidic features may be referred to as channels.

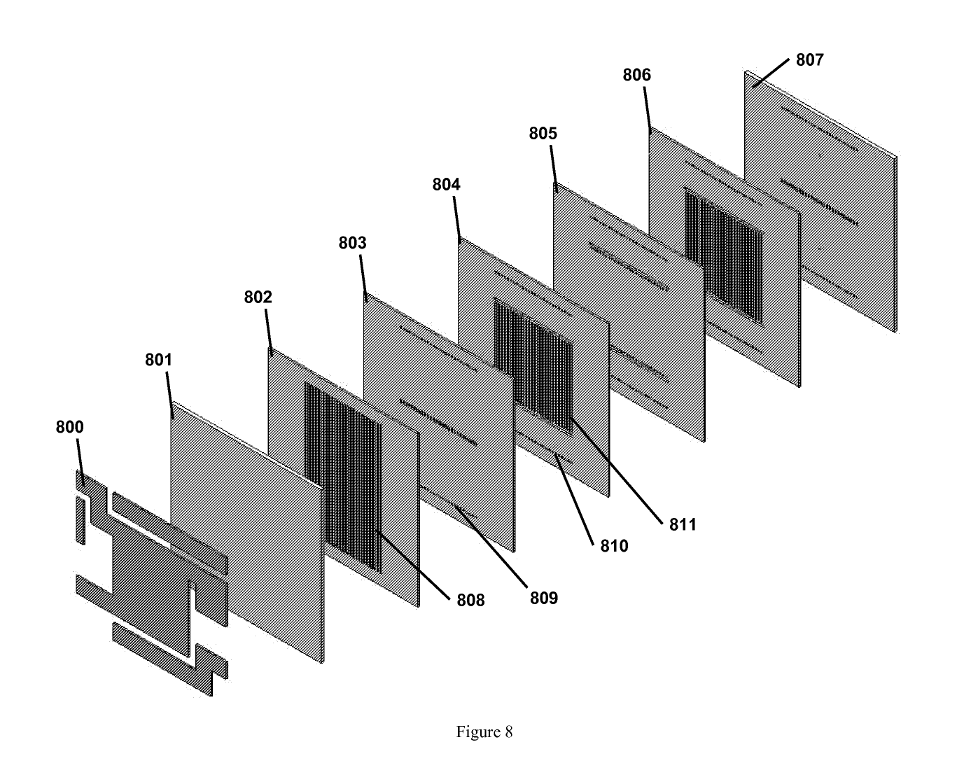

FIG. 8 is an exploded view of a unit showing the individual layers. For example, seven layers 801, 802, 803, 804, 805, 806, 807 may be provided as well as a metallization layer 800. In some embodiments, the seven layers may be formed of a ceramic material, a cermet material, or a metal-matrix composite. In some embodiments, the metallization may be formed from a material that may include copper, aluminum, silver, platinum, and/or tungsten. Any number of layers may be provided, including but not limited to 3, 4, 5, 6, 7, 8, 9, 10, 11, 12, 15, 20, or more layers

The layers may be provided such that slots 808, 811 and/or holes 809, 810 may be aligned such that microfluidic features are formed. These microfluidic features may be formed to provide a desired fluid flow arrangement within the heat transfer matrix. Some layers 801 may have no holes or slots, some layers 802 may have only slots 808, some layers 803 may have only holes 809, and some layers 804 may have slots 811 and holes 810. The layers may be thin sheets bonded together to form the heat transfer matrix.

In some embodiments, heat transfer matrix dimensions may vary. For example, a heat transfer matrix may have any dimensions. Varying the number or arrangement of units may vary the heat transfer matrix dimensions.

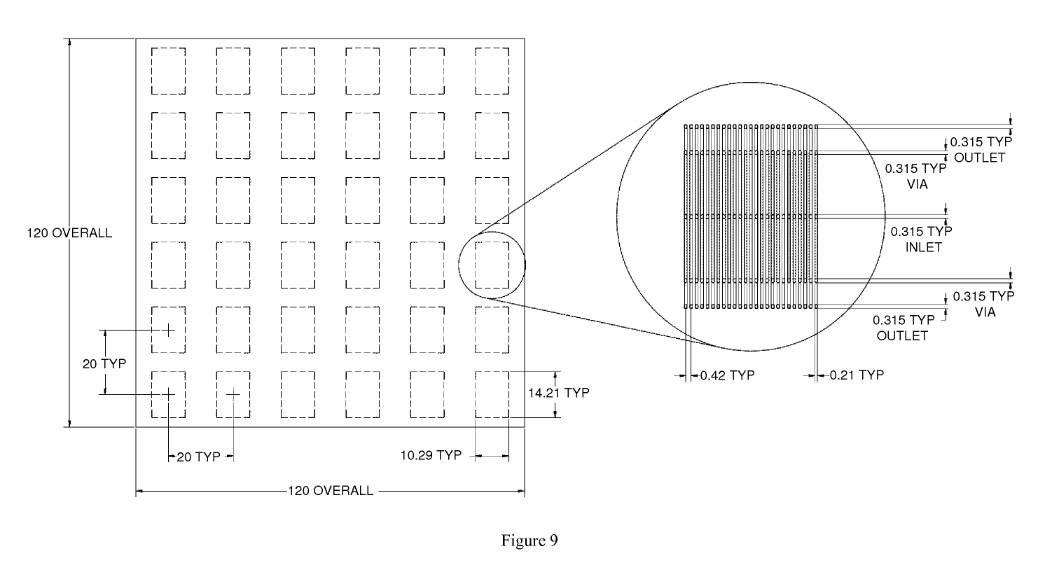

FIG. 9 shows a concentrating photovoltaic receiver cold plate in accordance with an embodiment of the invention. The dimensions provided in FIG. 9 are in millimeters and are provided by way of example only. Such dimensions provided may be post-sintering (pre-sintering dimensions may be about 17% larger). This design may be used in a concentrating photovoltaic receiver having a 6×6 array of photovoltaic cells and concentrator optics on 20 mm centers; each cell is approximately 10×11 mm. The overall photovoltaic receiver size may be about 120 mm by 120 mm. Alternatively, the receiver may have any other size where one or more dimension may be about 20 mm, 40 mm, 60 mm, 80 mm, 100 mm, 120 mm, 140 mm, 160 mm, 200 mm, 250 mm, 300 mm, 400 mm, 600 mm, 1000 mm or more or less. The photovoltaic cells and concentrator optics may include 4 mm center, 5 mm centers, 7 mm center, 10 mm centers, 13 mm centers, 15 mm centers, 18 mm centers, 20 mm centers, 22 mm centers, 25 mm centers, 30 mm centers, 40 mm centers, 50 mm centers, 70 mm centers, 100 mm centers or have any other spacing. The centers listed may be for one or more dimension listed; for example the centers may be the same or different along different dimensions. Each cell may have any dimensions where one or more dimensions may have be about 1 mm, 3 mm, 5 mm, 7 mm, 8 mm, 9 mm, 10 mm, 11 mm, 12 mm, 13 mm, 14 mm, 15 mm, 16 mm, 17 mm, 20 mm, 25 mm, 30 mm, 40 mm, 50 mm, 70 mm, 100 mm, or any other size.

Correspondingly, this cold plate may have 4, 9, 16, 25, 36, 49, or 64 clusters of microchannels (represented by the dashed rectangles in FIG. 9); each cluster may contain M microchannels (in a M×1 array), where M is a positive real integer. In some embodiments, any number of microchannels may be provided. For example, 1-100 microchannels may be provided in a cluster, where M is a number falling between 1 and 100. In other examples, about 2, 5, 10, 15, 20, 25, 30, 35, 40, 50, 60, 70, 75, 80, 90, or more microchannels may be provided in a cluster. Each microchannel may use the flow pattern shown in FIG. 6C, FIG. 6B, or may have any other flow pattern described herein. The ceramic layers have a post-firing thickness falling within the range of 0.05 to 3 mm each. Any thicknesses may be utilized, which may include but are not limited to 0.05 mm, 0.07 mm, 0.09 mm, 0.1 mm, 0.12 mm, 0.13 mm, 0.14 mm, 0.15 mm, 0.17 mm, 0.19 mm, 0.2 mm, 0.23 mm, 0.25 mm, 0.3 mm, 0.35 mm, 0.4 mm, 0.5 mm, 0.7 mm, 1.0 mm, 1.5 mm, 2 mm, or more.

A microchannel may have any diameter or other cross-sectional dimension. For example, a microchannel may have a 0.21 mm diameter or other dimension. In other examples, a microchannel may have a 0.05 mm, 0.1 mm, 0.15 mm, 0.17 mm, 0.19 mm, 0.20 mm, 0.22 mm, 0.23 mm, 0.25 mm, 0.27 mm, 0.30 mm, 0.31 mm, 0.32 mm, 0.35 mm, 0.4 mm, 0.5 mm, 0.7 mm, 1.0 mm, or more diameter or other dimension. A hole defining a via may or may not be circular, elliptical, square, rectangular, triangular, hexagonal, octagonal, or have any other shape or form. The dimensions defining a via cross section may vary in different directions, or may remain the same.

Microchannels may be spaced apart at any distance. In some examples, if a width of a microchannel is W, where W is any positive real number, the distance between the centers of the microchannels may be 2W. For example, if the width of a microchannel is 0.1 mm, 0.18 mm, 0.2 mm, 0.21 mm, 0.23 mm, or 0.25 mm the center to center distance between microchannels may be about 0.2 mm, 0.36 mm, 0.40 mm, 0.42 mm, 0.46 mm, or 0.5 mm respectively. Alternatively, the distances may be about 1.01W, 1.05W, 1.1W, 1.3W, 1.5W, 1.7 W, 1.9W, 2W, 2.5W, 3W, 4W, 5W, 7W, 10W, or any other distance. Microchannels may have a center to center distance of about 0.1 mm, 0.2 mm, 0.3 mm, 0.4 mm, 0.5 mm, 0.6 mm, 0.7 mm, 0.8 mm, 0.9 mm, 1 mm, 1.5 mm, 2 mm, 3 mm, 4 mm or any other value. In some embodiments, microchannels may have a center to center distance falling within the range of 0.1 to 1.2 mm, 0.2 to 0.8 mm, or 0.3 to 0.5 mm.

In some implementations, it may be preferable to have larger part sizes. The microfluidic features may be arranged into groups. There may be large areas of solid ceramic (or other heat transfer matrix materials) in “alleys” between the groups of microfluidic features. The alleys may just serve to hold the part together. In some embodiments, fixturing features may be added in those areas, or the areas may be cored out for faster debinding.

A heat transfer matrix may have one or more layers. The layer of a heat transfer matrix may include slots and/or holes. In some embodiments, the slots may be parallel and/or perpendicular to one another. In some embodiments the slots may go all the way through a layer, while in other embodiments, the slots may be formed into a layer but may not go all the way through a layer. In the latter case, a hole may or may not be in fluid communication with the slot.

The heat transfer matrix may include one or more slots and/or holes as discussed elsewhere herein. Additionally, the heat transfer matrix may have a metallization pattern on one or more surface. One or more solar cells may be soldered onto a portion of the metallization pattern.

Any discussion of dimensions or ranges of dimensions are illustrated and provided by way of example only. Any dimensions may be used for the heat transfer matrix, the units, and/or the microfluidic features.

A heat transfer matrix may be fabricated according to any technique known in the art. For example, various machining or lithographic techniques may be used. Another method of fabrication may include a rapid prototyping method. Layers may be deposited, which may include features such as holes or slots. The holes or slots may be filled with a sacrificial material. Layers may be deposited in this fashion. At the end, a solvent may be used to remove the sacrificial material. The fabrication process may depend on a material used to form the layers of the heat transfer matrix.

For example, for a ceramic heat transfer matrix, a green tape consisting of ceramic powder in an organic binder may be used for layers. A laser drill or mechanical punch may be used to create desired features in the layers. The layers may then be stacked with accurate registration and laminated together. A stencil thick-film metallization paste may be applied to the layers. The layers may then be debound and sintered. Then circuit traces may be electroplated onto the thick-film metallization.

In another example, for a cermet heat transfer matrix, wafers of a silicon-aluminum alloy or metal-matrix composite may be used. The wafers may be laser drilled to achieve the desired fluidic features. The wafers may be stacked with accurate registration and vacuum brazed together. The stack may include dissimilar wafer materials to alternately provide electrical insulation and electrical conduction, and the conductive wafers may be photoetched or otherwise patterned to form circuit traces.

In an additional example, if a heat transfer matrix is formed of a metal-matrix composite, an electrically insulating layer may be deposited onto the surface of the stack or on individual layers by a process such as sputtering, plasma-spraying, or spin-coating.

### III. Dense-Array Secondary Concentration

The various cold plate materials and configurations allow a dense-array secondary concentration in accordance with another aspect of the invention. The secondary optics may be more closely packed than the solar cells. For example, the cross-sectional area of each secondary optic may be greater than the area covered by a solar cell. For example, an optical receiver may have a densely-packed m×n array of optical concentrators, where m and n are integers greater than or equal to 1. The array of optical concentrators may direct light to a less densely-packed m×n array of photovoltaic cells. The spaces between the photovoltaic cells may be described as alleys.

Thus, the secondary optics may enable clear alleys between solar cells on a receiver (or other chips). The alleys may be used for busbars, electrical interconnections, and bypass diodes. This may enable higher electrical efficiency and the use of less expensive cells and diodes, while providing the optical equivalent of a fully dense array of cells.

It should be understood from the foregoing that, while particular implementations have been illustrated and described, various modifications can be made thereto and are contemplated herein. It is also not intended that the invention be limited by the specific examples provided within the specification. While the invention has been described with reference to the aforementioned specification, the descriptions and illustrations of the preferable embodiments herein are not meant to be construed in a limiting sense. Furthermore, it shall be understood that all aspects of the invention are not limited to the specific depictions, configurations or relative proportions set forth herein which depend upon a variety of conditions and variables. Various modifications in form and detail of the embodiments of the invention will be apparent to a person skilled in the art. It is therefore contemplated that the invention shall also cover any such modifications, variations and equivalents.

What is claimed is:

1. A heat exchanger for transferring heat to or from a moving fluid, comprising a thermally conductive solid body having one or more heat transfer surfaces; and one or more internal fluid passages, wherein the fluid consecutively flows:
(a) in a first direction substantially normal to and toward a heat transfer surface;
(b) in a second direction substantially parallel to the said heat transfer surface;
(c) in a third direction substantially normal to and toward the said heat transfer surface;
(d) in a fourth direction substantially parallel to the said heat transfer surface, and substantially opposite to the second direction;
(e) in a fifth direction substantially normal to and toward the said heat transfer surface; then
(f) in a sixth direction substantially parallel to the said heat transfer surface, and substantially opposite the fourth direction; and
(g) in a seventh direction substantially normal to the said heat transfer surface.

2. An electronic package comprising:
(a) one or more semiconductor devices;
(b) a plurality of electrically conductive circuit traces; and
(c) a thermally conductive dielectric solid body having a coefficient of thermal expansion of more than 0.50 times that of one or more of the semiconductor device(s), and less than 2.0 times that of the one or more semiconductor device(s), wherein the circuit traces are provided on the thermally conductive dielectric solid body, and wherein the one or more semiconductor devices are affixed to the circuit traces and/or the thermally conductive dielectric solid body along one or more thermal interface surfaces; and
wherein heat is transferred to a fluid flowing through a plurality of fluid passages within the thermally conductive dielectric solid body wherein the fluid flows:
(i) in a first direction substantially normal to and toward a thermal interface surface,
(ii) in a second direction substantially parallel to the said thermal interface surface, and
(iii) in a third direction substantially normal to and toward the said thermal interface surface.

3. The electronic package of claim 2, wherein the fluid further flows:
(iv) in a fourth direction substantially parallel to the said thermal interface surface, and substantially opposite to the said second direction,
(v) in a fifth direction substantially normal to and toward the said thermal interface surface,
(vi) in a sixth direction substantially parallel to the said thermal interface surface, and substantially opposite the said fourth direction, and
(vii) in a seventh direction substantially normal to the said thermal interface surface.

4. The electronic package of claim 2, wherein at least one of the semiconductor devices is a photovoltaic cell.

5. The electronic package of claim 2, wherein at least one of the semiconductor devices is a diode, transistor, or integrated circuit.

6. The electronic package of claim 2, wherein the solid body primarily comprises an oxide or nitride ceramic, or a mixture thereof, and has a thermal conductivity of greater than 5 W m⁻¹ K⁻¹.

7. A concentrating photovoltaic receiver comprising:
(a) a plurality of light-concentrating optical devices having their entrance apertures arranged in an m×n planar rectangular array, wherein m and n are integers greater than or equal to 1;
(b) an m×n planar rectangular array of photovoltaic cells, arranged so that each cell is illuminated by light exiting from at least one of the said light-concentrating optical devices;
(c) a plurality of electrically conductive circuit traces; and
(d) a thermally conductive dielectric solid body having a coefficient of thermal expansion of more than 0.50 times that of the photovoltaic cells, and less than 2.0 times that of the photovoltaic cells,
wherein the circuit traces are provided on the thermally conductive dielectric solid body, and wherein the photovoltaic cells are affixed to the circuit traces; and
wherein heat is transferred to a fluid flowing through a plurality of fluid passages within the thermally conductive dielectric solid body.

8. The concentrating photovoltaic receiver of claim 7, wherein the solid body primarily comprises an oxide or nitride ceramic, or a mixture thereof, and has a thermal conductivity of greater than 5 W m⁻¹ K⁻¹.

9. The concentrating photovoltaic receiver of claim 7, wherein the light-concentrating optical devices are attached to or integral with a common transparent substrate or superstrate having a coefficient of thermal expansion not greater than 1.5 times that of the photovoltaic cells.

10. A solar receiver comprising:
a photovoltaic cell; and
a cold plate connected to the photovoltaic cell,
wherein the cold plate comprises a material with a coefficient of thermal expansion that is substantially the same as the coefficient of thermal expansion for the photovoltaic cell, and
wherein heat is transferred from the photovoltaic cell to the cold plate.

11. A heat transfer matrix for use of cooling a solar cell comprising:
a solid structure;
at least one inlet in the solid structure;
at least one outlet in the solid structure; and
at least one fluid passage through the solid structure connecting the inlet and the outlet,
wherein a fluid flows through the fluidic passage, and
wherein the solid structure is formed of a material with a coefficient of thermal expansion that falls within a predetermined range relative to the coefficient of thermal expansion of the solar cell.

12. An electronic package comprising:
one or more semiconductor devices;
a plurality of electrically conductive circuit traces;
a thermally conductive solid body formed of an electrically insulating material, and having a coefficient of thermal expansion of more than 0.50 times that of the semiconductor device(s), and less than 2.0 times that of the one or more semiconductor devices,
wherein the circuit traces are provided on the thermally conductive solid body, and wherein the one or more semiconductor devices contact the circuit traces of the thermally conductive solid body along one or more thermal interfaces;
wherein heat is transferred to a fluid flowing through a plurality of fluid passages within the thermally conductive solid body wherein the flow direction is alternately parallel to and normal to the thermal interfaces of the semiconductor devices.

13. The electronic package of claim 12, in which the semiconductor devices are photovoltaic cells.

14. The electronic package of claim 13, in which a densely-packed m×n array of optical concentrators directs light to a less densely-packed m×n array of photovoltaic cells,
wherein m and n are integers greater than or equal to 1.

15. A microfluidic heat exchanger comprising:
two substantially planar opposing surfaces, wherein a first planar surface is in thermal contact with a heat acquisition surface and a second planar surface is formed with an inlet and an outlet; and
a plurality of microfluidic channels formed between the two substantially planar opposing surfaces, wherein the microfluidic channels are in fluid communication with the inlet and the outlet.

16. The microfluidic heat exchanger of claim 15 wherein the plurality of microfluidic channels include at least two microfluidic channels that are orthogonal to one another.
